(19) United States
(12) Patent Application Publication
(10) Pub. No.: US 2021/0262081 A1
(43) Pub. Date: Aug. 26, 2021

(54) DEPOSITION APPARATUS AND DEPOSITION METHOD

(71) Applicant: SAMSUNG ELECTRONICS CO., LTD., Suwon-si (KR)

(72) Inventors: Minsung Lee, Hwaseong-si (KR); Youngkwan Cha, Hwaseong-si (KR); Yountaek Ryu, Hwaseong-si (KR); Kyungwoo Park, Hwaseong-si (KR); Woonyoung Choi, Bucheon-si (KR); Ducksu Kim, Suwon-si (KR); Jeongyub Lee, Yongin-si (KR); Changseung Lee, Yongin-si (KR)

(73) Assignee: SAMSUNG ELECTRONICS CO., LTD., Suwon-si (KR)

(21) Appl. No.: 16/920,913

(22) Filed: Jul. 6, 2020

(30) Foreign Application Priority Data
Feb. 26, 2020 (KR) 10-2020-0023842

(51) Int. Cl. C23C 14/54; C23C 14/04; C23C 14/34

(52) U.S. Cl. CPC C23C 14/54; C23C 14/24; C23C 14/34; C23C 14/042

(57) ABSTRACT

A deposition apparatus forms a material layer on a substrate in a deposition chamber. Provided in the deposition chamber are at least one deposition material providing device that provides a deposition material to the substrate, a deposition mask that defines a deposition area on the substrate, and a stage that supports the substrate. The stage is movable in X and Y directions in a plane parallel to the substrate.

### CROSS-REFERENCE TO RELATED APPLICATION

This application is based on and claims priority under 35 U.S.C. § 119 to Korean Patent Application No. 10-2020-0023842, filed on Feb. 26, 2020, in the Korean Intellectual Property Office, the disclosure of which is incorporated by reference herein in its entirety.

### BACKGROUND

### 1. Field

The disclosure relates to a deposition apparatus that vaporizes a deposition material and deposits the deposition material on a substrate.

### 2. Description of Related Art

A deposition apparatus forms a deposition material by physical and chemical methods in a deposition chamber and deposits the deposition material on a substrate, for example, a wafer, to form a desired material layer on the substrate. A deposition mask defines an area where a material layer is to be formed on the substrate.

In a deposition apparatus according to related art, a target and substrate are fixedly positioned in the deposition chamber. When the material layer is formed on various positions of the substrate, it is difficult to form the material layer with the same deposition rate and the same film quality on all areas of the substrate because the distance from the target varies depending on a deposition position. In order to cover a large substrate, for example, the entire area of a substrate having a size of 8 inches or more, a target size or a target-substrate spacing needs to increase. This may lead to an increase in a target price and enlargement of the deposition chamber. In addition, it is difficult to perform various deposition processes in the deposition chamber.

### SUMMARY

A deposition apparatus is provided capable of performing uniform deposition with respect to the entire area of a substrate.

A deposition apparatus is provided capable of performing various deposition processes in one deposition chamber.

Additional aspects will be set forth in part in the description which follows and, in part, will be apparent from the description, or may be learned by practice of embodiments of the disclosure.

In accordance with an aspect of the disclosure, a deposition apparatus includes a deposition chamber; a stage provided inside the deposition chamber to support a substrate; at least one deposition material providing device configured to provide a deposition material to the substrate; and a deposition mask positioned between the at least one deposition material providing device and the substrate to define an area on the substrate on which the deposition material is to be deposited, wherein the stage is movable in a plane parallel to the substrate.

The at least one deposition material providing device may include a plurality of deposition material providing devices.

The plurality of deposition material providing devices may be disposed such that for each deposition material providing device from among the plurality of deposition material providing devices, the effective area of the deposition material providing device at least partially overlaps another effective area of another deposition material providing device from among the plurality of deposition providing devices.

The deposition apparatus may further include a frame on which the stage is supported; and flexible bellows configured to connect the stage and the frame.

The stage may be movable in a direction orthogonal to the substrate.

The at least one deposition material providing device may be further configured to physically vaporize a target to form the deposition material.

The deposition apparatus may further include a voltage applier configured to apply a voltage to the target.

The voltage applier may be further configured to apply a pulsed radio frequency (RF) voltage to the target.

The voltage applier may be further configured to apply a pulsed direct current (DC) voltage and a pulsed RF voltage to the target.

The deposition apparatus may further include a gas supplier configured to supply a gas around the target.

The at least one deposition material providing device may include the target that is a precursor of the deposition material; and a gas supply pipe configured to guide the gas supplied around the target from the gas supplier.

The at least one deposition material providing device may be further configured to form the deposition material by a chemical reaction.

In accordance with an aspect of the disclosure, a deposition method includes arranging at least one deposition material providing device in a deposition chamber, the at least one deposition material providing device including a target, a substrate, and a deposition mask defining a deposition area on the substrate; moving the substrate in a plane parallel to the substrate to align the deposition area with an effective area of the at least one deposition material providing device; and forming a material layer in the deposition area by performing a deposition process on the target.

The arranging of the at least one deposition material providing device may include arranging a plurality of deposition material providing devices in the deposition chamber.

The deposition method may further include arranging the plurality of deposition material providing devices such that for each deposition material providing device from among the plurality of deposition material providing devices, the effective area of the deposition material providing device at least partially overlaps another effective area of another deposition material providing device from among the plurality of deposition providing devices.

The moving the substrate may include aligning the deposition area with a common effective area in which the effective areas of the plurality of deposition material providing devices overlap.

The forming of the material layer may include simultaneously performing the deposition process on at least two targets among respective targets of the plurality of deposition material providing devices.

The forming of the material layer may include sequentially performing the deposition process on respective targets of the plurality of deposition material providing devices.

The plurality of deposition material providing devices may be disposed such that for each deposition material providing device from among the plurality of deposition material providing devices, the effective area of the deposition material providing device at least partially overlaps the effective area of each other deposition material providing device from among the plurality of deposition providing devices.

The at least one deposition material providing device may include a shower head configured to provide a gas to the substrate.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic configuration diagram of a deposition apparatus according to an embodiment;

FIG. 2 shows an effective area of a deposition material providing device;

FIG. 3 is a diagram showing a deposition method according to an embodiment;

FIG. 4 is a schematic configuration diagram of a deposition apparatus according to an embodiment;

FIG. 5 is a diagram showing an effective area formed by a first deposition material providing device and a second deposition material providing device;

FIG. 6 is a diagram showing an example of an area selective combination deposition process;

FIGS. 7A and 7B are diagrams showing examples of a layered combination deposition process;

FIG. 8 is a schematic configuration diagram of a deposition apparatus according to an embodiment, in which a substrate is spaced from a target;

FIG. 9 shows the substrate approaching the target in the deposition apparatus according to an embodiment illustrated in FIG. 8; and

FIG. 10 is a schematic configuration diagram of a deposition apparatus according to an embodiment.

### DETAILED DESCRIPTION

Reference will now be made in detail to embodiments, examples of which are illustrated in the accompanying drawings, wherein like reference numerals refer to like elements throughout. In this regard, embodiments may have different forms and should not be construed as being limited to the descriptions set forth herein. Accordingly, embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

In the drawings, the size of each element may be exaggerated for clarity and convenience of description.

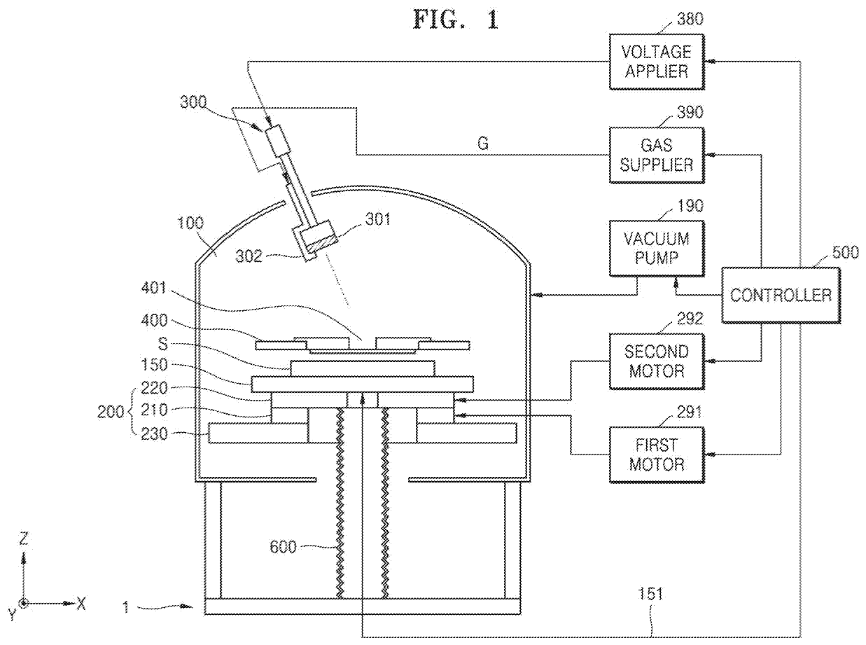

FIG. 1 is a schematic configuration diagram of a deposition apparatus according to an embodiment. Referring to FIG. 1, the deposition apparatus may include a deposition chamber 100, a stage 200 provided inside the deposition chamber 100 to support a substrate S, one or more deposition material providing devices 300 providing a deposition material to the substrate S, and a deposition mask 400 between the deposition material providing device 300 and the substrate S to define an area of the substrate S on which the deposition material is to be deposited. A controller 500 controls a deposition process.

Deposition methods may vary. Deposition methods, for example, may include a physical vapor deposition method (PVD) such as a thermal evaporation method, an E-beam evaporation method, or a sputtering method, a chemical vapor deposition method (CVD), an atomic layer deposition method (ALD), and the like. The deposition apparatus may form a material layer on the substrate S by using the sputtering method.

As shown in FIG. 1, the deposition material providing device 300 may physically vaporize a target 301, which is a precursor of the deposition material, to provide the deposition material to the substrate S. The deposition material providing device 300 may include the target 301. The inside of the deposition chamber 100 may be maintained at a predetermined vacuum pressure by a vacuum pump 190. A gas supplier 390 may supply gas G into the deposition chamber 100. The deposition material providing device 300 may include a gas supply line 302 that guides the gas G supplied from the gas supplier 390 around the target 301. Therefore, plasma may be formed locally around the target 301, and the supply amount of the gas G may be stably controlled.

A voltage applier 380 may apply a voltage to the target 301. Discharge may occur around the target 301. The gas G may be ionized around the target 301 to form the plasma, and the ionized gas G may collide with the target 301. Then, particles (e.g., a deposition material) may be separated from the surface of the target 301. The deposition material may then be attached to the deposition area of the substrate S as defined by the deposition mask 400 to form a material layer.

The voltage applied to the target 301 by the voltage applier 380 may be a direct current (DC) voltage. Sputtering using the DC voltage may be used when depositing a metal, semiconductor, or the like. The voltage applier 380 may apply a pulsed DC voltage to the target 301. Accordingly, the plasma may be prevented from being extinguished by ions of opposite polarity accumulated in an electrode, and thus, sputtering of a non-conductor target may be performed.

The voltage applier 380 may apply a radio frequency (RF) voltage to the target 301. According to the RF voltage, sputtering of a conductor target and a non-conductor target may be performed. The voltage applier 380 may apply a pulsed RF voltage to the target 301. Accordingly, the temperature rise of the substrate S may be suppressed, and thus, a stable deposition may be performed.

The DC pulse voltage and the RF pulse voltage may be related to particles, which are separated from the target 301 and transferred to the substrate S, for example, the flux of atoms and the energy of the atoms. When a high DC voltage is applied to the target 301, the atomic flux (e.g., the rate of diffusion of atoms away from the target 301) may increase. However, if the high DC voltage is continuously applied to the target 301, the target 301 may be damaged. Because the DC pulse voltage is repeatedly turned on/off, a higher DC pulse voltage may be applied to the target 301 compared to a continuous DC voltage, and thus, high atomic flux and high atomic energy may be secured.

In addition, the RF pulse voltage may be used to lower the atomic flux to the limit. In general, when the RF voltage is used, a deposition rate may be significantly lower than when the DC voltage is used. When the RF pulse voltage is used, a lower atomic flux may be obtained than when the continuous RF voltage is used. Therefore, a sufficient time for the atoms to be positioned on the substrate S may be secured to form a thin film material layer having a very high density on the substrate S.

The voltage applier 380 may simultaneously apply the DC pulse voltage and the RF pulse voltage to the target 301. Accordingly, the effect of DC sputtering, which shows high sputtering efficiency, and AC sputtering, which enables stable sputtering of conductors and non-conductors, may be simultaneously obtained.

The gas supplier 390 may supply an inert gas and a reactive gas around the target 301 to perform reactive sputtering. When using reactive sputtering, the reactive gas and particles separated from the conductor target may react to form various compounds such as oxides, carbides, sulfides, and nitrides to be deposited on the substrate S. For example, Ti may be employed as the target 301 and oxygen (O₂) gas may be supplied around the target 301 through the gas supply line 302 in an argon (Ar) gas atmosphere. Then, Ti separated from the target 301 may be reacted with oxygen to form TiO₂, and TiO₂ may be deposited on the substrate S.

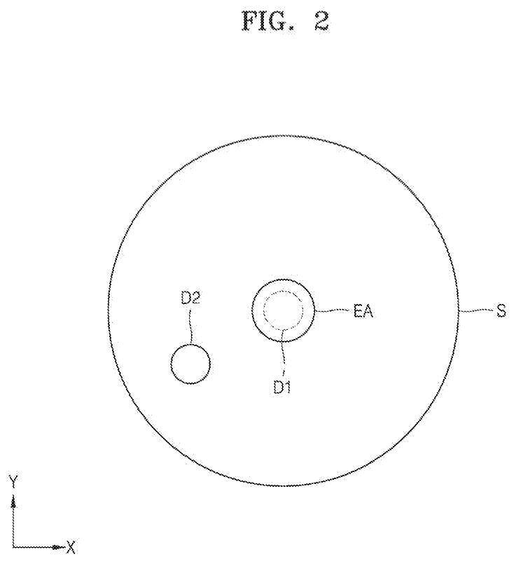

The formation rate and the film quality of the material layer formed on the substrate S by sputtering may depend on a distance between the target 301 and the deposition area on the substrate S, and the deposition material providing device 300 may have an effective area EA that may secure a uniform deposition quality. FIG. 2 shows the effective area EA of the deposition material providing device 300. As shown by the dashed line in FIG. 2, if a deposition area D1 of the substrate S is inside the effective area EA, a material layer of uniform quality may be formed in the deposition area D1. As shown by the solid line in FIG. 2, if a deposition area D2 is outside the effective area EA, a material layer formed in the deposition area D2 may be different from the material layer formed in the deposition area D1 in either or both of thickness and film quality. Therefore, in the case of forming material layers in various areas of the substrate S, several deposition processes need to be performed by varying deposition conditions, for example, a deposition time, according to a distance between the target 301 and a deposition position. In addition, a plurality of deposition masks 400 having a shape conforming to the deposition position need to be prepared, and the deposition masks 400 need to be replaced for each deposition process. Because the size of the effective area EA is proportional to the size of the target 301, a method of employing a large target 301 may be considered, but the price of a large target 301 may be expensive.

A method of disposing the target 301 and the deposition mask 400 on fixed positions, and moving the substrate S to dispose the deposition area inside the effective area EA may be employed. To this end, a stage 200, on which the substrate S is supported, may be movable in the X direction and the Y direction. The X direction and the Y direction may be directions perpendicular to each other in a plane parallel to the substrate S as shown in FIG. 1. The stage 200 may include a base stage 230, a first stage 210 supported to be movable with respect to the base stage 230 in either one of the X direction and the Y direction, and a second stage 220 supported to be movable with respect to the first stage 210 in the other direction of the X direction and the Y direction. The second stage 220 may support the substrate S.

For example, the first stage 210 may be movably supported on the base stage 230 in the X direction, and the second stage 220 may be movably supported on the first stage 210 in the Y direction. For example, a first lead screw extending in the X direction may be provided on the base stage 230, and a first engagement portion engaged with the first lead screw may be provided on the first stage 210. A first motor 291 may rotate the first lead screw to move the first stage 210 in the X direction. A second lead screw extending in the Y direction may be provided on the first stage 210, and a second engagement portion engaged with the second lead screw may be provided on the second stage 220. The second motor 292 may rotate the second lead screw to move the second stage 220 in the Y direction. As another method, the base stage 230 and the first stage 210 may be connected by a linear motor driven in the X direction, and the first stage 210 and the second stage 220 may be connected by a linear motor driven in the Y direction. In addition to this, the first stage 210 and the second stage 220 may be moved in the X and Y directions by using various methods.

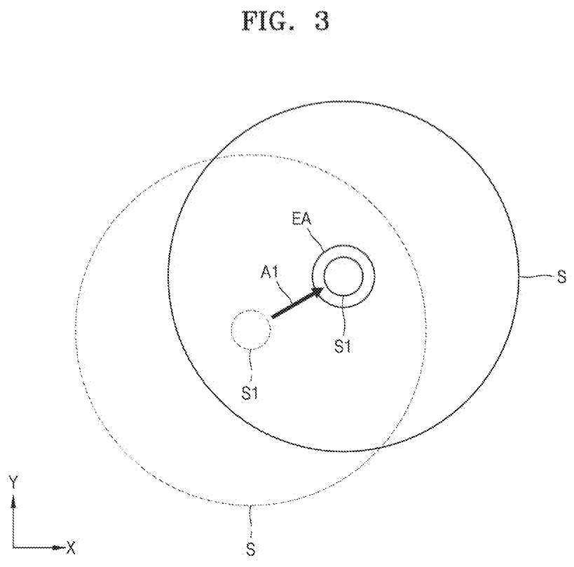

FIG. 3 is a diagram showing a deposition method according to an embodiment. The deposition method according to an embodiment may include arranging the deposition material providing device 300 having the target 301, the substrate S, and the deposition mask 400 defining a deposition area S1 on the substrate S in the deposition chamber 100, aligning the deposition area S1 of the substrate S with the effective area EA of the deposition material providing device 300, and performing a deposition process on the target 301 to form a material layer in the deposition area S1.

A deposition hole 401 of the deposition mask 400 (see FIG. 1) may be positioned in the effective area EA of the deposition material providing device 300. As shown by the dashed line in FIG. 3, the deposition area S1 may initially be positioned outside the effective area EA. A controller 500 may drive the first motor 291 and the second motor 292 to move the first stage 210 and the second stage 220 in the X and Y directions, respectively. Then, the substrate S may be moved in the direction A1 indicated by an arrow, and the deposition area S1 may be aligned with the effective area EA as shown by the solid line in FIG. 3. Then, sputtering may be performed by driving the voltage applier 380 and the gas supplier 390 to form a material layer in the deposition area S1. Next, the controller 500 may drive the first motor 291 and the second motor 292 to move the first stage 210 and the second stage 220 in the X direction and the Y direction and align the next deposition area of the substrate S with the effective area EA. Then, sputtering may be performed by driving the voltage applier 380 and the gas supplier 390 to form a material layer in the next deposition area of the substrate S. By repeating the above process, the material layer having a uniform film quality may be formed in first to nth (n is a natural number greater than 1) deposition areas of the substrate S.

Because distances between the target 301 and a plurality of deposition areas of the substrate S are constant, the formation speed and thickness of the material layer formed on the substrate S by sputtering may be also constant. That is, only the uniformity of the film quality in the small effective area EA, for example, the effective area EA of about 2 inches, with respect to the deposition material providing device 300 needs to be secured, and thus, even if the deposition position on the substrate S changes, reproducible deposition rate and film quality may be maintained. Therefore, the material layer having a uniform film quality may be formed in various areas of the substrate S. In addition, as long as the shape of the desired material layer does not change, it is not necessary to replace the deposition mask 400. Thus, a material layer having a uniform film quality may be formed in various areas of the substrate S by using one deposition mask 400. In addition, because only the uniformity of the film quality in the small effective area EA with respect to the deposition material providing device 300 needs to be secured, a uniform material layer may be formed on the entire area of a larger substrate S with the target 301 that is inexpensive and small. For example, a uniform material layer may be formed on an entire area of a substrate having a size of 8 inches or more using a target corresponding to an effective area of only 2 inches. The effect is very economically advantageous when various materials are used as the target 301.

Referring back to FIG. 1, to prevent the temperature of the substrate S from excessively rising in the sputtering process, a temperature adjuster 150 may be provided on the stage 200, for example, on the second stage 220. The substrate S may be mounted on the temperature adjuster 150.

The temperature adjuster 150 may include, for example, a cooler. The temperature adjuster 150 may include the cooler and a heater. The temperature adjuster 150 may include a temperature sensor that detects the temperature of the substrate S. The cooler may be implemented, for example, by a Peltier element array. The cooler may be implemented by a cooling plate through which cooling fluid supplied from the outside flows. The heater may be implemented by, for example, a resistance coil. The controller 500 may drive the heater of the temperature adjuster 150 to heat the substrate S to an appropriate temperature. In addition, the controller 500 may drive the cooler of the temperature adjuster 150 to cool the substrate S such that the temperature of the substrate S may not excessively rise during the sputtering operation. A driving signal line for driving the temperature adjuster 150 and a detection signal line of the temperature sensor may be connected to the controller 500.

A control signal line 151 including the driving signal line and the detection signal line needs to be drawn out from the deposition chamber 100 without being exposed to the inside of the deposition chamber 100. Referring to FIG. 1, the stage 200 may be supported on a frame 1 of a deposition apparatus. Because the first and second stages 210 and 220 are moved in the X and Y directions, the temperature adjuster 150 may be substantially moved in the X and Y directions. Therefore, the stage 200 and the frame 1 need to be connected by a flexible connecting member. According to an embodiment, the stage 200 and the frame 1 may be connected by flexible bellows 600. The control signal line 151 may pass through the inside of the bellows 600 and be connected to the controller 500.

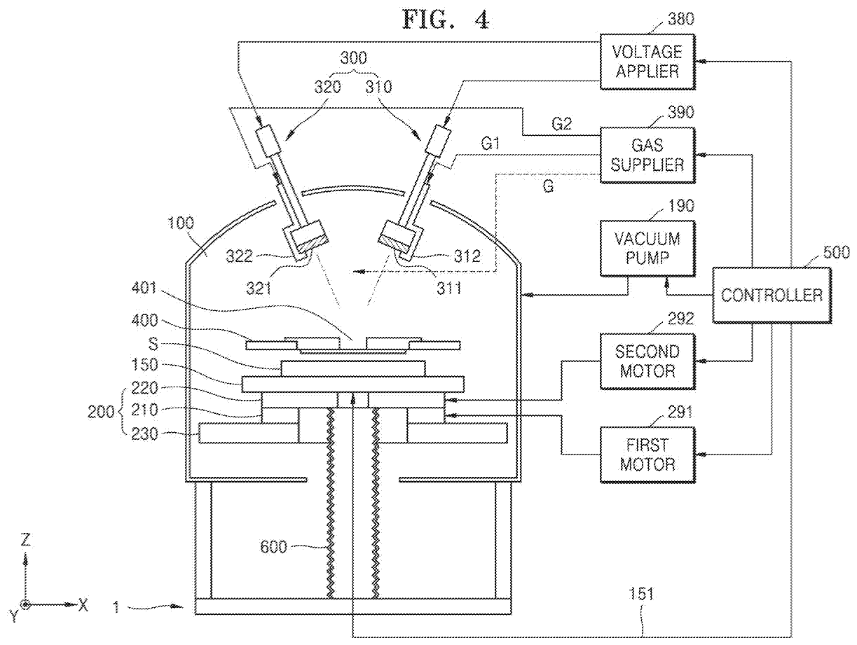

FIG. 4 is a schematic configuration diagram of a deposition apparatus according to an embodiment.

Recently, for the development of capacitor materials for dynamic random access memory (DRAM), the development of phase change materials and switching materials for phase-change random access memory (PRAM), and the development of metal oxide electrode materials, attempts have been made to overcome the technical limitations though a combination of two or more materials. In this case, two or more targets may be provided in the deposition chamber 100, and sputtering may be performed on the two or more targets simultaneously or sequentially.

The deposition apparatus of FIG. 4 is different from the deposition apparatus of an embodiment illustrated in FIG. 1 in that two targets are provided in the deposition chamber 100. Hereinafter, members having the same function are denoted by the same reference numerals, and redundant descriptions are omitted, and differences from the deposition apparatus of the embodiment shown in FIG. 1 are mainly described.

Referring to FIG. 4, the deposition material providing device 300 may include a plurality of deposition material providing devices, for example, a first deposition material providing device 310 and a second deposition material providing device 320. The first deposition material providing device 310 may include a first target 311, and the second deposition material providing device 320 may include a second target 321. The first target 311 and the second target 321 may be the same material, or different materials.

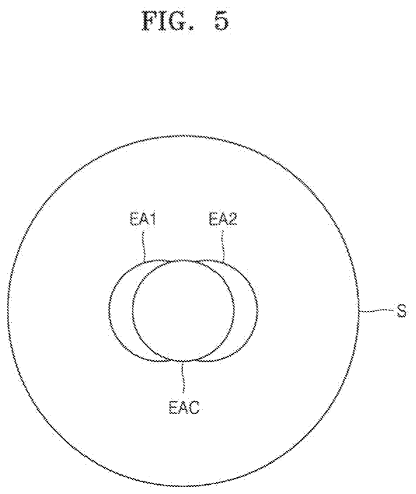

FIG. 5 is a diagram showing the effective area EA formed by the first deposition material providing device 310 and the second deposition material providing device 320. Referring to FIG. 5, the first deposition material providing device 310 has a first effective area EA1 and the second deposition material providing device 320 has a second effective area EA2. The first deposition material providing device 310 and the second deposition material providing device 320 may be arranged such that the first effective area EA1 and the second effective area EA2 overlap each other at least partially. For example, the first effective area EA1 and the second effective area EA2 may partially overlap each other. In this case, an area where the first effective area EA1 and the second effective area EA2 overlap may be referred to as a common effective area EAC. The first effective area EA1 and the second effective area EA2 may completely overlap each other, and the common effective area EAC may be the same as the first effective area EA1 and the second effective area EA2. When three or more deposition material providing devices are provided, the three or more deposition material providing devices may be arranged such that the effective areas overlap each other at least partially.

The inside of the deposition chamber 100 may be maintained at a predetermined vacuum pressure by the vacuum pump 190. The gas supplier 390 may supply a gas, for example, an inert gas, into the deposition chamber 100. The voltage applier 380 may apply voltages to the first target 311 and the second target 321. The voltages may include a DC voltage, a pulsed DC voltage, an RF voltage, a pulsed RF voltage, or the pulsed DC voltage and the pulsed RF voltage.

When the voltages are applied, discharge may occur around the first target 311 and the second target 321. The gas G may be ionized around the first target 311 and the second target 321 to form plasma, and the ionized gas G may collide with the first target 311 and the second target 321. Then, particles (a first deposition material and a second deposition material) may be separated from the surfaces of the first target 311 and the second target 321. The first deposition material and the second deposition material may then be attached to a specific area of the substrate S as defined by the deposition mask 400 to form a first material layer and a second material layer. With the above configuration, the first material layer and the second material layer may be formed on the substrate S.

The gas supplier 390 may supply different gases around the first target 311 and the second target 321. For example, the gas supplier 390 may supply a first gas G1 around the first target 311 and a second gas G2 around the second target 321. The first deposition material providing device 310 may include a first gas supply line 312 that guides the first gas G1 supplied from the gas supplier 390 around the first target 311. The second deposition material providing device 320 may include a second gas supply line 322 that guides the second gas G2 supplied from the gas supplier 390 around the second target 321. Accordingly, the first gas G1 may not affect the second target 321 and the second gas G2 may not affect the first target 311. In addition, the supply amounts of the first gas G1 and the second gas G2 may be individually controlled.

According to the above configuration, independent reactive sputtering with respect to the first target 311 and the second target 321 may be performed. For example, Ti may be employed as the first target 311 and oxygen (O₂) gas may be supplied around the first target 311 through the first gas supply line 312 in an argon (Ar) gas atmosphere. Then, Ti separated from the first target 311 may react with oxygen to form TiO₂ and TiO₂ may be deposited on the substrate S. In addition, Ti may be employed as the second target 321 and a nitrogen (N₂) gas may be supplied around the second target 321 through the second gas supply line 322 in the argon (Ar) gas atmosphere. Then, Ti separated from the second target 321 may react with nitrogen to form TiN and TiN may be deposited on the substrate S.

As another example, the gas supplier 390 may supply the same gas G around the first target 311 and the second target 321. In this case, the gas supplier 390 may supply the same gas G around the first target 311 and the second target 321 inside the deposition chamber 100 through a separate gas supply line as shown by the dashed line in FIG. 4. As another example, the gas G may be supplied around the first target 311 and the second target 321 through the first gas supply line 312 and the second gas supply line 322, respectively.

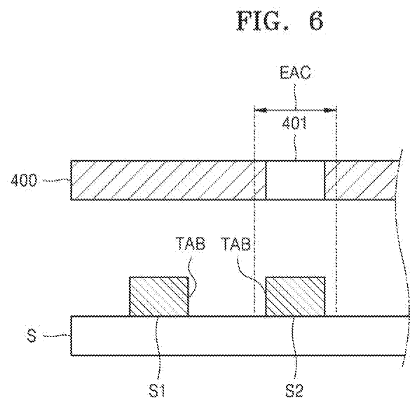

According to the above configuration, an area selective combination deposition process may be performed using the first and second deposition material providing devices 310 and 320. FIG. 6 is a diagram showing an example of an area selective combination deposition process. Referring to FIG. 6, deposition holes 401 of the deposition mask 400 may be aligned with the common effective area EAC. The controller 500 may drive the first and second motors 291 and 292 to move the first and second stages 210 and 220 in the X and Y directions to align the first deposition area S1 of the substrate S with the common effective area EAC. Then, a sputtering process may be performed on the first target 311 and the second target 321 at the same time such that a material layer TAB in which a first deposition material and a second deposition material are combined may be deposited on the first deposition area S1 of the substrate S. Next, the substrate S may be moved to align a second deposition area S2 with the common effective area EAC and a sputtering process may simultaneously be performed on the first target 311 and the second target 321 such that the material layer TAB in which the first deposition material and the second deposition material are combined may be formed in the second deposition area S2. When three or more deposition material providing devices are employed, a material layer having various material combinations may be formed by operating two or three or more deposition material providing devices for each deposition area.

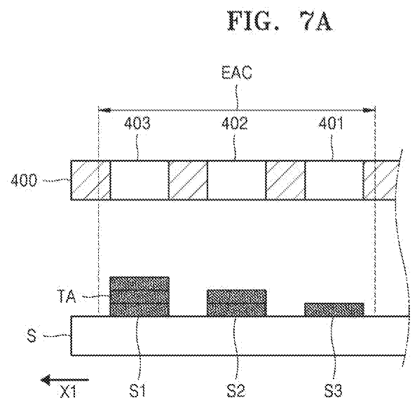

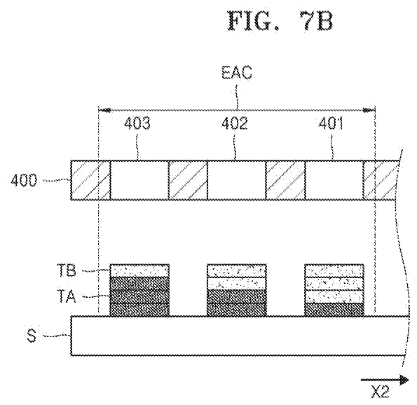

A layered combination deposition process may be performed using the first and second deposition material providing devices 310 and 320. FIGS. 7A and 7B are diagrams showing examples of a layered combination deposition process. Referring to FIG. 7A, a plurality of deposition holes 401, 402 and 403 may be provided in the deposition mask 400. The plurality of deposition holes 401, 402, and 403 may all be aligned with the common effective area EAC.

The controller 500 may drive the first and second motors 291 and 292 to move the first and second stages 210 and 220 in the X and Y directions such that the first deposition area S1 of the substrate S may be aligned with the deposition hole 401 of the deposition mask 400. At this time, the second deposition area S2 and the third deposition area S3 may not be positioned within the common effective area EAC. Then, a sputtering process may be performed on the first target 311 to form a first material layer TA in the first deposition area S1 of the substrate S. Next, the substrate S may be moved in the X1 direction to align the first deposition area S1 and the second deposition area S2 with the deposition holes 402 and 401, respectively, and perform the sputtering process on the first target 311 such that the first material layer TA may be formed in the first deposition area S1 and the second deposition area S2 of the substrate S. As described above, when the sputtering process is performed on the first target 311 while moving the substrate S in the X1 direction, as shown in FIG. 7A, the first material layers TA of different thicknesses may be formed on the first, second, and third deposition areas S1, S2, and S3.

Next, the third deposition area S3 of the substrate S may be aligned with the deposition hole 403 of the deposition mask 400 such that the first deposition area S1 and the second deposition area S2 are not positioned within the common effective area EAC. Then, the sputtering process may be performed on the second target 321 to form a second material layer TB in the third deposition area S3 of the substrate S. Next, the substrate S may be moved in the X2 direction (see FIG. 7B) to align the third deposition area S3 and the second deposition area S2 with the deposition holes 402 and 403, respectively, and perform the sputtering process on the second target 321 such that the second material layer TB may be formed in the third deposition area S3 and the second deposition area S2 of the substrate S. When the sputtering process is performed on the second target 321 while moving the substrate S in the X2 direction as described above, as shown in FIG. 7B, the second material layers TB of different thicknesses may be formed on the first, second, and third deposition areas S1, S2, and S3.

The deposition apparatus of the embodiment illustrated in FIG. 4 includes the two deposition material providing devices 310 and 320, but three or four or more deposition material providing devices may be provided in the deposition chamber 100 as necessary.

As described above, area selective combination deposition and layered combination deposition may be performed on the one substrate S in the one deposition chamber 100. In addition, a combination of a number of deposition holes and a number of targets may be used to implement various material combinations of two or three or more materials. Therefore, the deposition apparatus may be useful for developing various technologies, such as capacitor material development for dynamic random access memory (DRAM), phase changing material and switching material development for phase-change random access memory (PRAM), and metal oxide electrode material development.

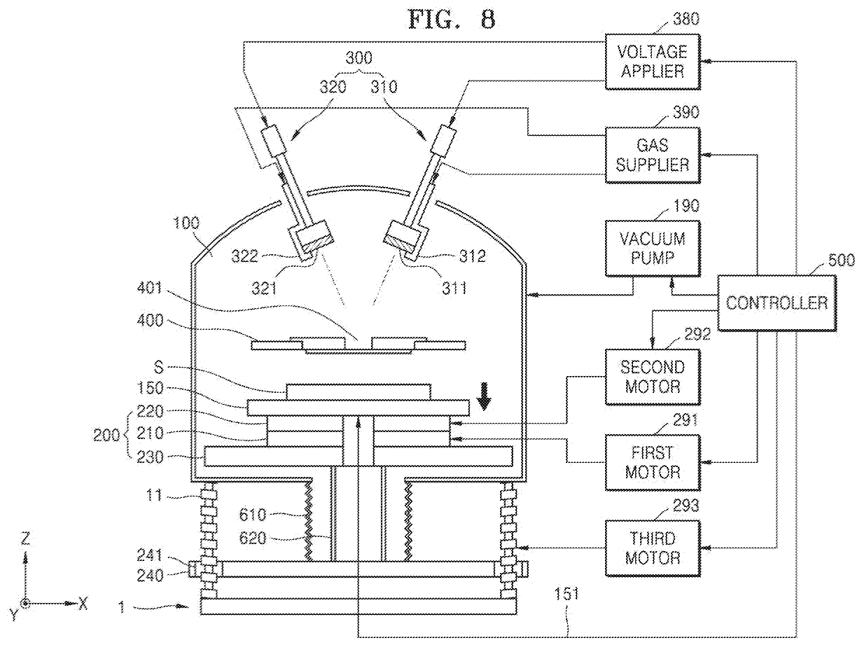

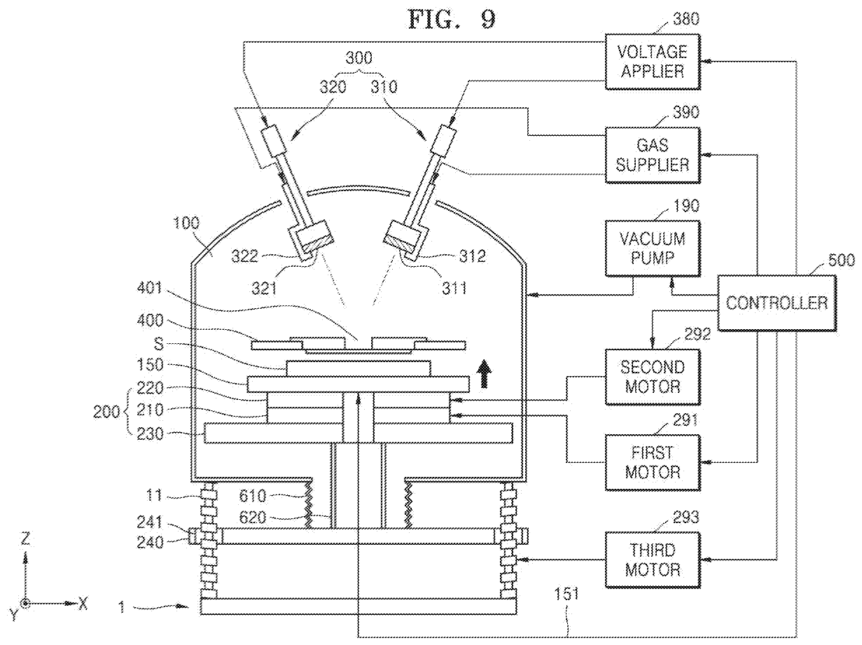

According to the type of a target, it may be necessary to adjust a distance between the target and the substrate S. In addition, in order to replace the substrate S or the deposition mask 400, the substrate S may need to be spaced apart from the target. To adjust the distance between the target and the substrate S, the substrate S may approach or may be separated from the target. To this end, the stage 200 may be moved in the Z direction as shown in FIGS. 8 and 9. The Z direction is a direction orthogonal to the X direction and the Y direction. In other words, the Z direction is a direction orthogonal to the substrate S. FIG. 8 is a schematic configuration diagram of a deposition apparatus according to an embodiment, in which the substrate S is spaced from a target. FIG. 9 shows the substrate S approaching a target in the deposition apparatus according to an embodiment illustrated in FIG. 8. The deposition apparatus of the embodiment shown in FIGS. 8 and 9 is different from the deposition apparatus of the embodiment shown in FIG. 4 in that the stage 200 is movable in the Z direction. Hereinafter, members having the same function are denoted by the same reference numerals, and redundant descriptions will be omitted, and differences from the deposition apparatus of the embodiment illustrated in FIG. 4 will be mainly described.

Referring to FIGS. 8 and 9, the substrate S may be moved in the X, Y, and Z directions with respect to the target and the deposition mask 400. To this end, the stage 200, on which the substrate S is supported, may be movable in the X direction, the Y direction, and the Z direction. The X direction and the Y direction are directions orthogonal to each other in a plane parallel to the substrate S, and the Z direction is a direction orthogonal to the X direction and the Y direction. In an embodiment, the stage 200 may include the base stage 230 supported to be movable in the frame 1 of the deposition apparatus in the Z direction, the first stage 210 supported to be movable with respect to the base stage 230 in the X direction or the Y direction, and the second stage 220 supported to be movable with respect to the first stage 210 in the other direction of the X direction and the Y direction. The second stage 220 may support the substrate S.

The first stage 210 may be movably supported on the base stage 230 in the X direction, and the second stage 220 may be movably supported on the first stage 210 in the Y direction. The connection of the base stage 230 and the first stage 210 and the connection of the first stage 210 and the second stage 220 may be performed by using various methods such as a combination of a lead screw and an engaging portion and a linear motor as described above. The controller 500 may drive the first motor 291 and the second motor 292 to move the first stage 210 and the second stage 220 in the X and Y directions, respectively.

The connection of the base stage 230 and the frame 1 may also be implemented by using various methods such as the combination of the lead screw and the engaging portion and the linear motor. The base stage 230 may be supported to be movable in the Z direction with respect to the frame 1 by the combination of the lead screw and the engaging portion. Referring to FIG. 8, a lead screw 11 extending in the Z direction may be provided in the frame 1. An engaging portion 241 spirally coupled to the lead screw 11 may be provided in a moving plate 240. The base stage 230 may be connected to the moving plate 240 by a hollow cylinder 620. A third motor 293 may rotate the lead screw 11 to move the base stage 230 in the Z direction.

A control signal line from the deposition chamber 100, for example, the control signal line 151 for driving the temperature adjuster 150, may be connected to the controller 500 through the inside of the hollow cylinder 620. The flexible bellows 610 which is stretchable may surround the hollow cylinder 620. One end of the bellows 610 may be connected to the moving plate 240, and the other end may be connected to the deposition chamber 100.

As illustrated in FIG. 8, the substrate S may be positioned at the bottom position. Sputtering may be performed at the bottom position, and replacement of the substrate S or the deposition mask 400 may then be performed. The controller 500 may drive the third motor 293 in the forward direction to raise the stage 200 to an arbitrary position in the Z direction. For example, the controller 500 may raise the stage 200 to the top position as shown in FIG. 9. The sputtering process may be performed at the bottom position, the top position, or any position between the bottom position and the top position. The structure in which the stage 200 shown in FIG. 8 is moved in the Z direction may be applied to the deposition apparatus according to an embodiment shown in FIG. 1.

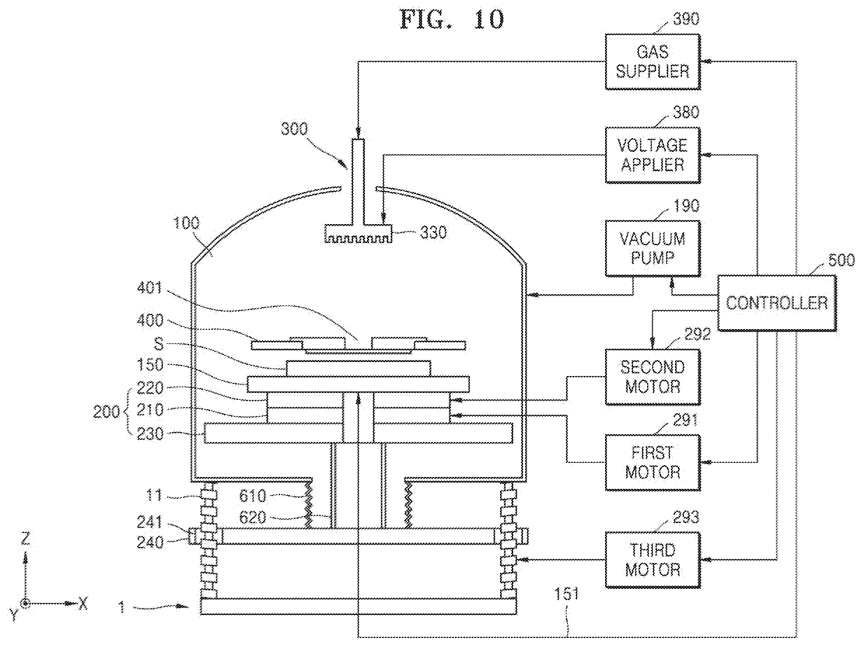

The deposition apparatus according to the embodiments described above may also be applied to a deposition apparatus employing a chemical vapor deposition method. FIG. 10 is a schematic configuration diagram of a deposition apparatus. The deposition apparatus according to an embodiment illustrated in FIG. 10 is different from the deposition apparatus according to an embodiment illustrated in FIG. 8 in that a shower head 330 is employed as the deposition material providing device 300.

Referring to FIG. 10, the deposition apparatus forms a material layer on the substrate S by using a chemical vapor deposition method. The inside of the deposition chamber 100 (a reaction chamber) may be maintained at a predetermined process temperature. For example, the controller 500 may maintain a temperature inside the deposition chamber 100 at the predetermined process temperature by driving the temperature adjuster 150 or a heater installed inside the deposition chamber 100. In the chemical vapor deposition method, because a process result or the quality of a thin film may vary depending on the process temperature, the controller 500 may drive the temperature adjuster 150 or the heater such that the temperature of the substrate S may vary according to the deposition position on the substrate S. The deposition material providing device 300 may include the shower head 330. One or more reaction gases supplied from the gas supplier 390 may be supplied into the deposition chamber 100 through the shower head 330. The reaction gas may be a precursor in the gas state. The reaction gas may cause a chemical reaction on the surface of the substrate S heated at a predetermined temperature to be reconfigured into a deposition material, and the deposition material may be deposited on the surface of the substrate S to form a material layer. When a natural chemical reaction is difficult or a high temperature is required due to the characteristics of the deposition material, a plasma environment may be provided inside the deposition chamber 100. For example, the voltage applier 380 may apply a voltage to the shower head 330. The voltage may be, for example, a RF voltage. Therefore, the reaction gas may be decomposed into a plasma state, and decomposed precursors may react to form a desired deposition material.

The above-described structure of the stage 200 movable in the X direction, the Y direction, and the Z direction may be applied to the deposition apparatus according to an embodiment illustrated in FIG. 10.

According to the above-described deposition apparatus and method of the embodiments, a uniform deposition may be performed on the entire area of a substrate. In addition, various deposition processes may be performed in one deposition chamber.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A deposition apparatus comprising:
a deposition chamber;
a stage provided inside the deposition chamber to support a substrate;
at least one deposition material providing device configured to provide a deposition material to the substrate; and
a deposition mask positioned between the at least one deposition material providing device and the substrate to define an area on the substrate on which the deposition material is to be deposited,
wherein the stage is movable in a plane parallel to the substrate.

2. The deposition apparatus of claim 1, wherein the at least one deposition material providing device comprises a plurality of deposition material providing devices.

3. The deposition apparatus of claim 2, wherein the plurality of deposition material providing devices are disposed such that for each deposition material providing device from among the plurality of deposition material providing devices, the effective area of the deposition material providing device at least partially overlaps another effective area of another deposition material providing device from among the plurality of deposition providing devices.

4. The deposition apparatus of claim 1, further comprising:
a frame on which the stage is supported; and
flexible bellows configured to connect the stage and the frame.

5. The deposition apparatus of claim 1, wherein the stage is movable in a direction orthogonal to the substrate.

6. The deposition apparatus of claim 1, wherein the at least one deposition material providing device is further configured to physically vaporize a target to form the deposition material.

7. The deposition apparatus of claim 6, further comprising a voltage applier configured to apply a voltage to the target.

8. The deposition apparatus of claim 7, wherein the voltage applier is further configured to apply a pulsed radio frequency (RF) voltage to the target.

9. The deposition apparatus of claim 7, wherein the voltage applier is further configured to apply a pulsed direct current (DC) voltage and a pulsed RF voltage to the target.

10. The deposition apparatus of claim 6, further comprising a gas supplier configured to supply a gas around the target.

11. The deposition apparatus of claim 10, wherein the at least one deposition material providing device comprises:
the target that is a precursor of the deposition material; and
a gas supply pipe configured to guide the gas supplied around the target from the gas supplier.

12. The deposition apparatus of claim 1, wherein the at least one deposition material providing device is further configured to form the deposition material by a chemical reaction.

13. A deposition method comprising:
arranging at least one deposition material providing device in a deposition chamber, the at least one deposition material providing device including a target, a substrate, and a deposition mask defining a deposition area on the substrate;
moving the substrate in a plane parallel to the substrate to align the deposition area with an effective area of the at least one deposition material providing device; and
forming a material layer in the deposition area by performing a deposition process on the target.

14. The deposition method of claim 13, wherein the arranging of the at least one deposition material providing device comprises arranging a plurality of deposition material providing devices in the deposition chamber.

15. The deposition method of claim 14, further comprising arranging the plurality of deposition material providing devices such that for each deposition material providing device from among the plurality of deposition material providing devices, the effective area of the deposition material providing device at least partially overlaps another effective area of another deposition material providing device from among the plurality of deposition providing devices.

16. The deposition method of claim 15, wherein the moving the substrate comprises aligning the deposition area with a common effective area in which the effective areas of the plurality of deposition material providing devices overlap.

17. The deposition method of claim 14, wherein the forming of the material layer comprises simultaneously performing the deposition process on at least two targets among respective targets of the plurality of deposition material providing devices.

18. The deposition method of claim 14, wherein the forming of the material layer comprises sequentially performing the deposition process on respective targets of the plurality of deposition material providing devices.

19. The deposition apparatus of claim 2, wherein the plurality of deposition material providing devices are disposed such that for each deposition material providing device from among the plurality of deposition material providing devices, the effective area of the deposition material providing device at least partially overlaps the effective area of each other deposition material providing device from among the plurality of deposition providing devices.

20. The deposition apparatus of claim 1, wherein the at least one deposition material providing device comprises a shower head configured to provide a gas to the substrate.
